(19) United States
(12) Patent Application Publication
(10) Pub. No.: US 2012/0194213 A1
(43) Pub. Date: Aug. 2, 2012

(54) PROBE CARD

(75) Inventors: Shigekazu Komatsu, Nirasaki City (JP); Kenichi Kataoka, Nirasaki City (JP)

(73) Assignee: Tokyo Electron Limited, Tokyo (JP)

(21) Appl. No.: 13/499,528

(22) PCT Filed: Aug. 16, 2010
(86) PCT No.: PCT/JP10/63830

§ 371 Date: Mar. 30, 2012

(30) Foreign Application Priority Data
Oct. 1, 2009 (JP) 2009-229697

(51) Int. Cl. G01R 1/067

(52) U.S. Cl. 324/756.03

(57) ABSTRACT

A probe card for testing electrical characteristics of an object to be tested includes a plurality of contactors for contacting the object during the testing; a plurality of tester chips configured to send and receive electric test signals to and from the object to test the electrical characteristics of the object; and a conductive portion electrically connecting the contactors with the corresponding tester chips, the contactors being arranged on a lower surface of the conductive portion. The probe card further includes a pressing portion configured to press the conductive portion against the object during the testing, so that a pressing force is applied between the contactors and the object.

### FIELD OF THE INVENTION

The present invention relates to a probe card for testing electrical characteristics of an object to be tested.

### BACKGROUND OF THE INVENTION

For example, testing of electrical characteristics of an electronic circuit such as IC and LSI formed on a semiconductor wafer (hereinafter, referred to as “wafer”) is carried out by using, e.g., a probe apparatus having a probe card, a mounting table holding the wafer and the like. The probe card generally includes plural contactors for contacting electrode pads of the electronic circuit on the wafer, a support plate supporting the contactors on its lower surface, a circuit board installed above the support plate and transmitting an electric test signal to each of the contactors, and the like. Further, by transmitting the electric signal from the circuit board to each of the contactors while each of the contactors contacts each of the electrode pads of the wafer, testing of the electronic circuit on the wafer is conducted.

In order to appropriately perform testing of the electrical characteristics of the electronic circuit, the contactors and the electrode pads need to contact each other at a predetermined contact pressure. Accordingly, conventionally, it has been proposed that, for example, as shown in FIG. 15, a fluid chamber 204 which is filled with a gas or the like and extensible/contractible is provided between a circuit board 201 and a support plate 203 supporting plural contactors 202 in a probe card 200. Wirings 205 connected with the contactors 202 are formed on the support plate 203 and the support plate 203 extends to the outside of the fluid chamber 204. Outside the fluid chamber 204, the wirings 205 of the support plate 203 are connected to the circuit board 201 and, thus, the contactors 202 and the circuit board 201 are electrically connected to each other. Then, when testing the electronic circuit, the support plate 203 is pressed by introducing a gas or the like into the fluid chamber 204 such that the contactors 202 and the electrode pads contact each other at a predetermined contact pressure (Japanese Patent Application Publication No. H7-94561(JP07-94561)).

However, in recent years, a pattern of the electronic circuit is miniaturized. Also, the electrode pads are miniaturized and a gap between the electrode pads is narrowed. Further, since the wafer itself also becomes large-sized, the number of the electrode pads formed on the wafer is greatly increasing. Accordingly, a great number of contactors and corresponding wirings need to be provided even in the probe card.

Under this situation, as described above, in order to connect the wirings 205 of the support plate 203 and the circuit board 201 to each other at the outside of the fluid chamber 204, the wirings 205 need to be formed at very small intervals in a narrow region at the outside of the fluid chamber 204, which is actually difficult.

Further, when the wirings 205 are arranged outside the fluid chamber 204, since the lengths of the wirings from the contactors 202 to the circuit board 201 are different, a method for transmitting the electric signal from the circuit board 201 to the contactors 202 may be different for each of the contactors 202 during testing.

### SUMMARY OF THE INVENTION

The present invention has been conceived in view of the above, and it is an object of the present invention to appropriately perform testing while stabilizing contact between an object to be tested and contactors when testing electrical characteristics of the object to be tested such as a wafer having plural electrode pads.

In order to achieve the object, in accordance with an aspect of the present invention, there is provided a probe card for testing electrical characteristics of an object to be tested including a plurality of contactors for contacting the object during the testing; a plurality of tester chips configured to send and receive electric test signals to and from the object to test the electrical characteristics of the object; a conductive portion electrically connecting the contactors with the corresponding tester chips, the contactors being arranged on a lower surface of the conductive portion; and a pressing portion configured to press the conductive portion against the object during the testing, so that a pressing force is applied between the contactors and the object.

In accordance with the above embodiment, since the tester chips for sending and receiving the electric test signals to/from the object to be tested are provided on the conductive portion electrically connecting the contactors with the tester chips, there is no need to form the wirings at very small intervals within a narrow region as in a conventional case, and it is possible to place the conductive portion without difficulty. Thus, the probe card of the present invention may respond to even an object to be tested wherein a number of electrode pads are formed on the wafer.

Further, since the tester chips are provided on the conductive portion, it is possible to achieve the same wiring length between the contactors and the circuit board. Therefore, methods for transmitting the electric signals from the circuit board to the contactors are the same for each of the contactors. Consequently, by using the probe card of the present invention, it is possible to appropriately test the electrical characteristics of the object to be tested while stabilizing contact between the contactors and the object to be tested.

In accordance with another aspect of the present invention, there is provided a probe card for testing electrical characteristics of an object to be tested, including: a circuit board having a through-hole; a plurality of contactors for contacting the object; a contactor support plate provided below the circuit board to support the contactors; and a pressing portion configured to pass through the through-hole of the circuit board from an upper side of the circuit board during the testing to press the contactor support plate against the object, so that a pressing force is applied between the contactors and the object.

### BRIEF DESCRIPTION OF THE DRAWINGS

FIG. 1 is a longitudinal cross sectional view schematically showing a configuration of a probe apparatus having a probe card in accordance with an embodiment of the present invention.

FIG. 2 is a transverse cross sectional view schematically showing a configuration of the probe card.

FIG. 3 is an explanatory diagram showing a state where testing is performed by using the probe apparatus.

FIG. 4 is an explanatory diagram showing a state where testing is performed by using the probe apparatus.

FIG. 5 is an explanatory diagram showing a state where tester chips are arranged in an upright posture.

FIG. 6 is a transverse cross sectional view schematically showing a configuration of the probe card when the tester chips are arranged in an upright posture.

FIG. 7 is a longitudinal cross sectional view schematically showing a configuration of a probe card in accordance with another embodiment.

FIG. 8 is a longitudinal cross sectional view schematically showing a configuration of a probe card in accordance with another embodiment.

FIG. 9 is a longitudinal cross sectional view schematically showing a configuration of a probe card in accordance with another embodiment.

FIG. 10 is a longitudinal cross sectional view schematically showing a configuration of a probe apparatus having a probe card in accordance with another embodiment.

FIG. 11 is an explanatory diagram showing a state where testing is performed by using the probe apparatus in accordance with another embodiment.

FIG. 12 is an explanatory diagram showing a state where testing is performed by using the probe apparatus in accordance with another embodiment.

FIG. 13 is a longitudinal cross sectional view schematically showing a configuration of a probe card in accordance with another embodiment.

FIG. 14 is a longitudinal cross sectional view schematically showing a configuration of a probe card in accordance with another embodiment.

FIG. 15 is a longitudinal cross sectional view schematically showing a configuration of a conventional probe card.

FIG. 16 is a longitudinal cross sectional view schematically showing a configuration of a probe card.

### DETAILED DESCRIPTION OF THE EMBODIMENTS

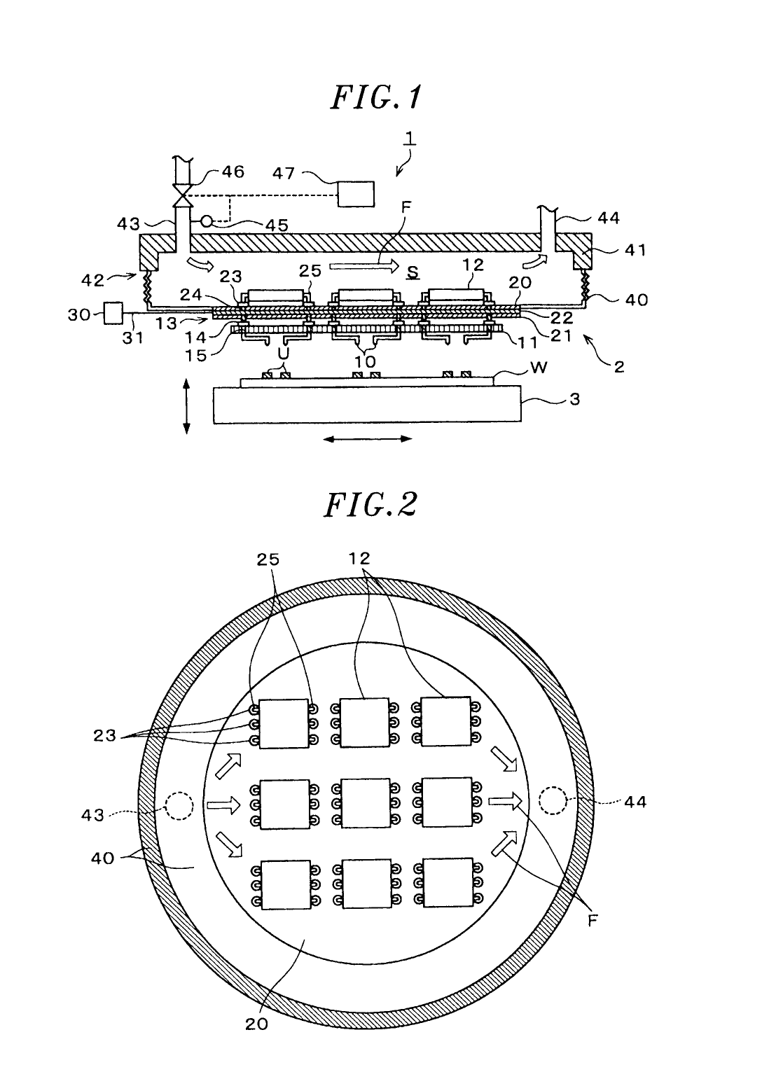

Hereinafter, an embodiment of the present invention will be described. FIG. 1 is a longitudinal cross sectional view schematically showing a configuration of a probe apparatus 1 having a probe card in accordance with the embodiment of the present invention. FIG. 2 is a transverse cross sectional view schematically showing a configuration of the probe card in accordance with the embodiment of the present invention.

The probe apparatus 1 includes, e.g., a probe card 2, and a mounting table 3 for mounting thereon a wafer W serving as an object to be tested. The probe card 2 is disposed above the mounting table 3.

The probe card 2 is formed, e.g., in a substantially disc shape. The probe card 2 includes plural contactors 10 contacting electrode pads U of the wafer W during testing, a contactor support plate 11 supporting the contactors 10 on its lower surface, plural tester chips 12 for sending electric test signals to the wafer W through the contactors 10, and a conductive portion 13 which electrically connects the contactors 10 to the tester chips 12.

The contactor support plate 11 is formed, e.g., in a substantially disc shape to face the mounting table 3. The contactors 10 supported on the lower surface of the contactor support plate 11 are arranged at positions corresponding to the electrode pads U of the wafer W. Plural connection terminals 14 are provided on an upper surface of the contactor support plate 11 at positions corresponding to the contactors 10. The connection terminals 14 are electrically connected to the contactors 10 respectively through connection wirings 15. The contactors 10 are made of a conductive material of metal such as a nickel alloy with excellent mechanical properties. Further, the contactors 10 preferably have an elastic structure capable of absorbing a difference in height between the electrode pads U if the electrode pads U have different heights in a local region on the wafer W. Although cantilever type contactors are illustrated as the contactors 10 in FIG. 1, without being limited thereto, the contactors applicable to the present invention may be various contactors having elasticity, e.g., MEMS needles or Pogo pins. Further, the contactor support plate 11 is formed of an elastic material, e.g., stainless steel, or an iron-nickel alloy such as Alloy 42, Invar, and Kovar. By forming the contactor support plate 11 using a material, such as Alloy 42, having a thermal expansion coefficient substantially equal to that of the wafer W, it is possible to prevent misalignment of the wafer W and the contactors 10 due to thermal expansion.

The conductive portion 13 is provided above the contactor support plate 11. The conductive portion 13 may include, e.g. flexible printed circuits (FPC) having, e.g., two insulating layers 20 and 21 with flexibility, and a wiring layer 22 formed between the two insulating layers 20 and 21. Connection terminals 23 are provided on an upper surface of the insulating layer 20. The connection terminals 23 are electrically connected to the connection terminals 14 of the contactor support plate 11 through connection wirings 24. Further, the number of layers of the conductive portion may be set arbitrarily without being limited to that of this embodiment.

As shown in FIGS. 1 and 2, the tester chips 12 are arranged on the upper surface of the conductive portion 13 at positions corresponding to the contactors 10. Further, as shown in FIG. 1, the tester chips 12 are arranged in parallel to the conductive portion 13 and the contactor support plate 11. The tester chips 12 are electrically connected to the connection terminals 23 through connection wirings 25. Accordingly, the tester chips 12 are electrically connected to the contactors 10. Further, a measuring device 30 is provided outside the probe card 2 to send and receive electric signals for measurement and provide power to the tester chips 12. The measuring device 30 is electrically connected to the tester chips 12 through the conductive portion 13 and a connection wiring 31 connected to the conductive portion 13. The tester chips 12 are small chips which are converted from a so-called tester conventionally used to test electrical characteristics of various kinds of objects to be tested and specialized to test only one kind of object to be tested.

Connected to an outer peripheral portion of the conductive portion 13 is, as shown in FIG. 1, a cylindrical elastic member 40 which is extensible and contractible in a vertical direction. For example, a metal bellows or the like may be used as the elastic member 40. The elastic member 40 is bonded to a lower surface of a support member disposed above the tester chip 12 to support the conductive portion 13 and the contactor support plate 11 provided on a lower surface of the conductive portion 13. The conductive portion 13 and the elastic member 40 are hermetically connected to each other. Also, the elastic member 40 and the support member 41 are hermetically connected to each other. Therefore, the conductive portion 13, the elastic member 40 and the support member 41 constitute a fluid chamber 42 serving as a pressing portion having a region S that can be filled with a fluid. The support member 41 is provided in communication with a supply pipe 43 serving as a fluid inlet for supplying a fluid into the region S and a discharge pipe 44 serving as a fluid outlet for discharging a predetermined amount of fluid from the region S.

A compressed air supply source (not shown) for supplying, e.g., a compressed air as a fluid is connected to the supply pipe 43. As the fluid, e.g., liquid such as pure water may be used without being limited to gas. Further, the supply pipe 43 is provided with a pressure gauge 45 for measuring the pressure of compressed air in the supply pipe 43. Further, a valve 46 is provided in the supply pipe 43. Opening/closing of the valve 46 is controlled by a control unit 47 on the basis of a pressure detection signal of the pressure gauge 45. Further, if a predetermined amount of compressed air controlled by opening/closing of the valve 46 is introduced into the region S, the elastic member 40 may be extended vertically, and thus the conductive portion 13 and the contactor support plate 11 may be bent downward. Accordingly, by supplying a fluid in the fluid chamber 42, the fluid chamber 42 serves as a pressing portion applying a predetermined contact pressure to the contactors 10 during testing. Further, the discharge pipe 44 is provided to discharge a predetermined amount of compressed air from the region S, for example as shown in FIGS. 1 and 2, such that an airflow F of the predetermined amount of compressed air is formed as a flow of fluid in the region S to cool the tester chips 12 accommodated in the fluid chamber 42. Thus, the discharge pipe 44 and the supply pipe 43 are arranged to face each other, e.g., at an outer peripheral portion of the support member 41 as shown in FIG. 1 because all of the tester chips 12 in the fluid chamber 42 are cooled by the airflow F. The amount of compressed air exhausted from the discharge pipe 44 is appropriately set according to the amount of heat generated from the tester chips 12 and the pressure in the fluid chamber 42. Further, the supply pipe 43 and the discharge pipe 44 are provided in communication with the support member 41 in FIGS. 1 and 2, the supply pipe and the discharge pipe 44 may be provided in communication with the elastic member 40, or may be provided in communication with the conductive portion 13 if they may be positioned without interfering with the test.

The mounting table 3 is configured to be movable, e.g., horizontally and vertically, and can move the mounted wafer W in three dimensions.

The probe apparatus 1 of this embodiment is configured as described above. Next, there will be described a method for testing electrical characteristics of an electronic circuit of the wafer W, which is carried out in the probe apparatus 1.

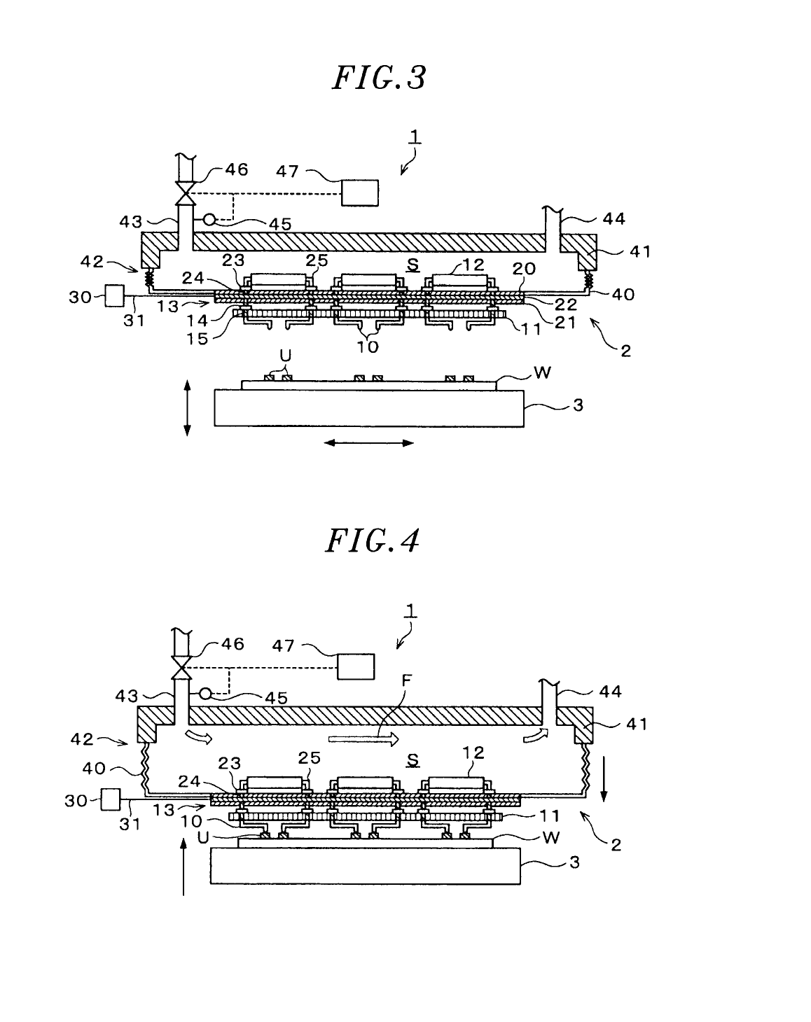

At the beginning of testing, as shown in FIG. 3, the compressed air is not supplied into the fluid chamber 42, and the elastic member 40 is in a contracted state.

Further, when the wafer W is mounted on the mounting table 3, the mounting table 3 is moved up to a predetermined position as shown in FIG. 4. At the same time or thereafter, the compressed air is supplied into the fluid chamber 42 from the supply pipe 43, and the fluid chamber 42 is filled with a predetermined amount of compressed air. Then, the elastic member 40 is extended vertically to press down the contactor support plate 11 through the conductive portion 13. Accordingly, the contactors 10 are put in contact with the electrode pads U of the wafer W respectively at a predetermined contact pressure.

Then, while the wafer W is pressed to the contactors 10 at a predetermined contact pressure, the electric test signals are transmitted from the tester chips 12 to the respective electrode pads U of the wafer W sequentially passing through the conductive portion 13 and the contactors 10, thereby testing the electrical characteristics of the electronic circuit on the wafer W.

In accordance with the above embodiment, since the tester chips 12 for sending and receiving the electric test signals are provided on the conductive portion 13 electrically connecting the contactors 10 with the tester chips 12, there is no need to form the wirings at very small intervals within a narrow region as in a conventional case, and it is possible to place the conductive portion 13 without difficulty. Thus, the probe card 2 of this embodiment may respond to even a case where a number of the electrode pads U are formed on the wafer W.

Further, since the tester chips 12 are provided on the conductive portion 13, it is possible to achieve the same wiring length between the contactors 10 and the tester chips 12. Therefore, methods for transmitting the electric signals from the tester chips 12 to the contactors 10 are the same for each of the contactors 10, thereby conducting reliable testing. Further, since the wirings between the tester chips 12 and the contactors 10 may be formed to be very short, it is possible to facilitate testing of the electrical characteristics using high-speed signals.

Further, since the contactors 10 have elasticity, it is possible to absorb a difference in height between the electrode pads U if the electrode pads U have different heights in a local region on the wafer W. Meanwhile, if the wafer W or an upper surface of the mounting table 3 has a slope, distortion, positioning error or the like, since the conductive portion 13 and the contactor support plate 11 provided on the lower surface of the conductive portion 13 have flexibility and the fluid is introduced into the region S to apply a uniform contact pressure, stable contact can be achieved at a predetermined contact pressure on the entire probe card 2.

As described above, by using the probe card 2 of this embodiment, while making the electrode pads U of the wafer W in stable contact with the contactors 10 at a predetermined contact pressure, it is possible to properly test the electrical characteristics of the electronic circuit on the wafer W.

Further, in accordance with the above embodiment, in addition to the supply pipe 43 supplying a fluid in the region S, the discharge pipe 44 is provided to form the airflow F in the region S. Accordingly, it is possible to appropriately cool the tester chips 12 by the airflow F. Thus, there is no need to provide an additional cooling unit in order to cool the tester chips 12, and it is possible to miniaturize the probe card 2.

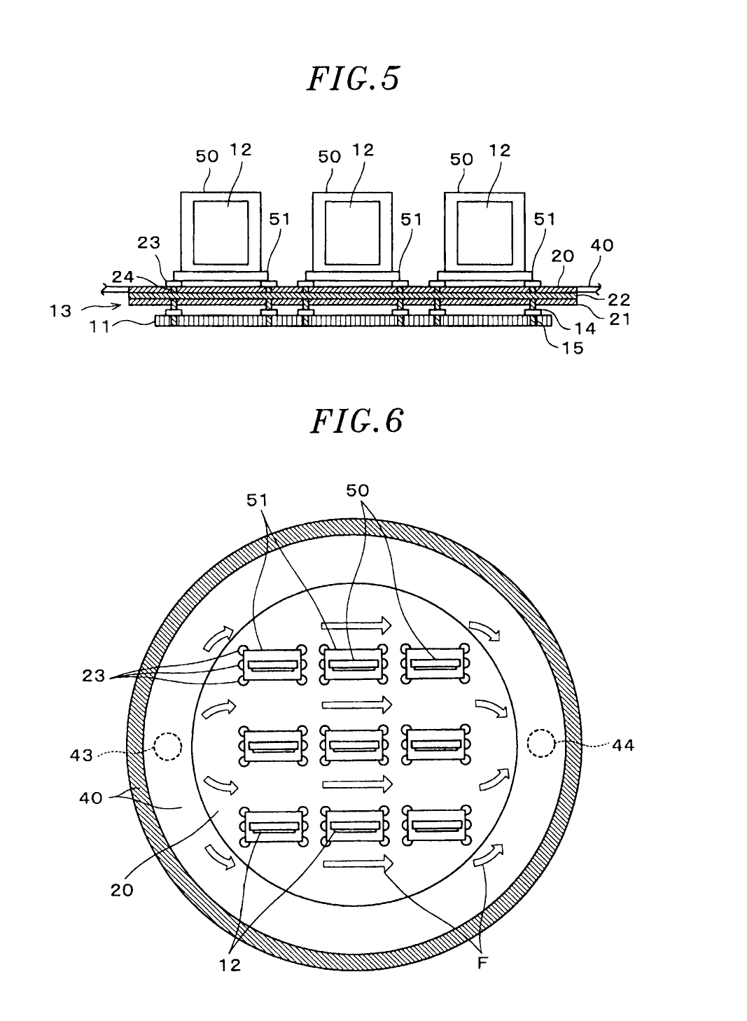

Although the tester chips 12 are arranged in parallel to the conductive portion 13 in the above embodiment, for example, as shown in FIG. 5, mounting substrates 50 may be arranged in an upright posture on the conductive portion 13 at positions corresponding to the contactors 10, and the tester chips 12 may be mounted on the mounting substrates 50. By providing the tester chips 12 in an upright posture, it is possible to arrange a large number of the tester chips 12 on the conductive portion 13 compared to a case where the tester chips 12 are arranged in parallel to the conductive portion 13. Accordingly, a greater number of the contactors may be provided on the probe card 2, and it is possible to respond to even a case where a greater number of the electrode pads U are formed on the wafer W.

Further, the mounting substrates 50 and the conductive portion 13 may be electrically connected to each other, as shown in FIG. 5, via connectors 51 which are connecting members provided on the conductive portion 13 and detachable from the mounting substrates 50. Accordingly, even if the electrical characteristics of an object to be tested cannot be tested by the tester chips 12, it is easy to replace the tester chips 12 with other tester chips 12 corresponding to the object to be tested, thereby conducting testing of various types of objects to be tested.

Further, the mounting substrates 50 for mounting the tester chips 12 may be arranged, e.g., as shown in FIG. 6, in parallel to the airflow F formed in the region S by the supply pipe 43 and the discharge pipe 44. Accordingly, since the mounting substrates 50 and the tester chips 12 function as distributing plates and the compressed air supplied from the supply pipe 43 is rapidly discharged from the discharge pipe 44, it is possible to efficiently cool the tester chips 12.

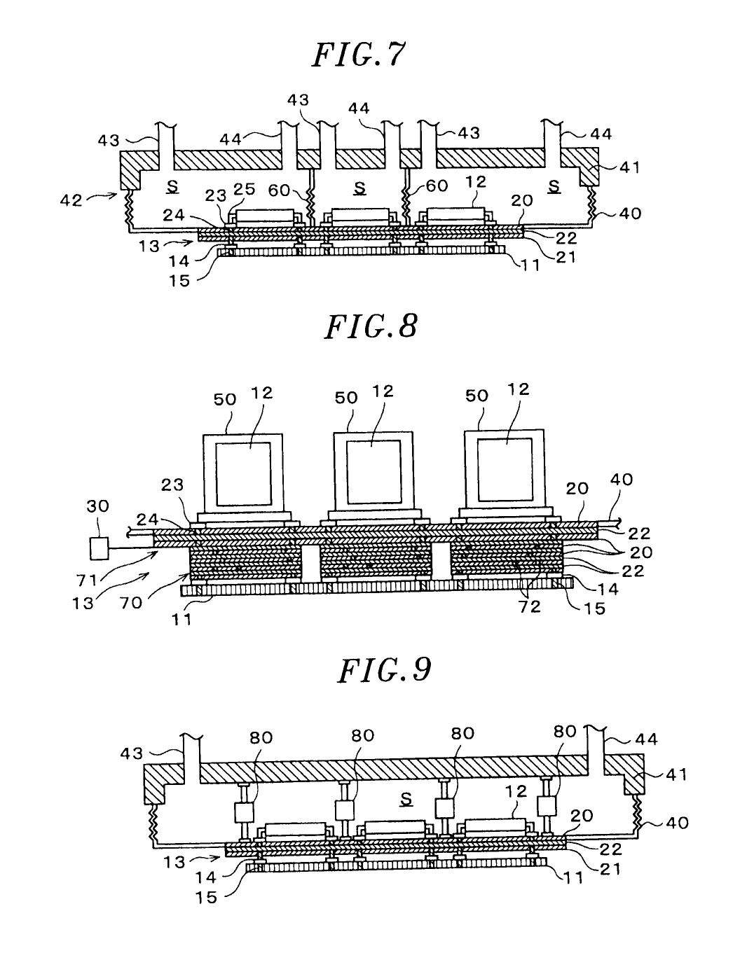

Although one fluid chamber 42 is formed by the conductive portion 13, the elastic member 40 and the support member 41 in the above embodiment, for example, as shown in FIG. 7, partition walls 60 may be provided between the conductive portion 13 and the support member 41 to divide the region S, thereby forming plural fluid chambers 42. As the partition walls 60, e.g., metal bellows or the like may be used in the same way as the elastic member 40. In this case, the supply pipe 43, the discharge pipe 44 and the valve 46 provided in the supply pipe 43 are provided for each of the fluid chambers 42. Accordingly, it is possible to independently control the contact pressure for each of the fluid chambers 42 by the control unit 47.

Further, in the above embodiment, the conductive portion 13 is formed by two insulating layers 20 and 21 and one wiring layer 22. However, for example, if a large number of the contactors 10 are provided in the probe card 2, a region that can be used for wiring is limited in the conductive portion 13, and it is necessary to form the wirings at very small intervals, thereby making the manufacture difficult. Therefore, in order to facilitate formation of wiring, for example, as shown in FIG. 8, the conductive portion 13 may be formed to include contactor wiring portions 70 electrically connecting the contactors 10 with the tester chips 12, and an external wiring portion 71 electrically connecting the tester chips 12 with the measuring device 30 provided outside the tester chips 12. The contactor wiring portions 70 and the external wiring portion 71 are formed by stacking plural insulating layers 20 and plural wiring layers 22 similarly to the conductive portion 13. Further, the wiring layers 22 are electrically connected to each other by connection wirings 72. In this case, the contactor wiring portions 70 are formed by stacking multiple layers below the positions corresponding to the tester chips 12, and the external wiring portion 71 is provided on upper surfaces of the contactor wiring portions 70. By forming the contactor wiring portions 70 in a multilayer structure, there is no need to form the wirings at very small intervals and it makes the manufacture easy.

Further, by forming the contactor wiring portions 70 in a multilayer structure, the contactor wiring portions 70 may lose flexibility. However, if a fixed number of the tester chips 12 are provided in the probe card 2, since an external wiring of the tester chips 12 and the probe card 2 is constant regardless of the number of the contactors 10, the external wiring portion 71 does not have a multilayer structure as in the contactor wiring portions 70. Accordingly, even if the probe card 2 is provided with a large number of the contactors 10, as shown in FIG. 8, only the contactor wiring portions 70 have a multilayer structure, and the flexibility of the external wiring portion 71 is maintained. Thus, even if the contactor wiring portions 70 have a multilayer structure, the entire conductive portion 13 maintains flexibility, so that the electrode pads U of the wafer W can be put in stable contact with the contactors 10 at a predetermined contact pressure.

Although a contact pressure is applied to the contactors 10 by using the fluid chamber 42 serving as a pressing portion in the above embodiment, for example, as shown in FIG. 9, a pressure may be applied to the contactors 10 by using plural pressing mechanisms 80 provided on the conductive portion 13 instead of the fluid chamber 42. In this case, as shown in FIG. 9, the pressing mechanisms 80 are arranged to press parts of the upper surface of the conductive portion 13 where the tester chips 12 are not arranged. Upper portions of the pressing mechanisms 80 are supported by the support member 41. In this case, the contact pressure of each of the pressing mechanisms 80 is independently controlled by the control unit 47. As the pressing mechanisms 80, e.g., a hydraulic cylinder, electric actuator or the like may be used. Further, in case of using the pressing mechanisms 80 serving as a pressing portion, the fluid chamber 42 is no longer needed, but the fluid chamber 42 may still be used to perform cooling of the tester chips 12. Also, if cooling of the tester chips 12 is performed without using the fluid chamber 42, for example, the conductive portion 13 may be directly supported by lower surfaces of the pressing mechanisms 80. Accordingly, this eliminates the need to provide the elastic member 40. Thus, the tester chips 12 are exposed to the outside such that the heat of the tester chips 12 is dissipated to the outside of the probe card 2.

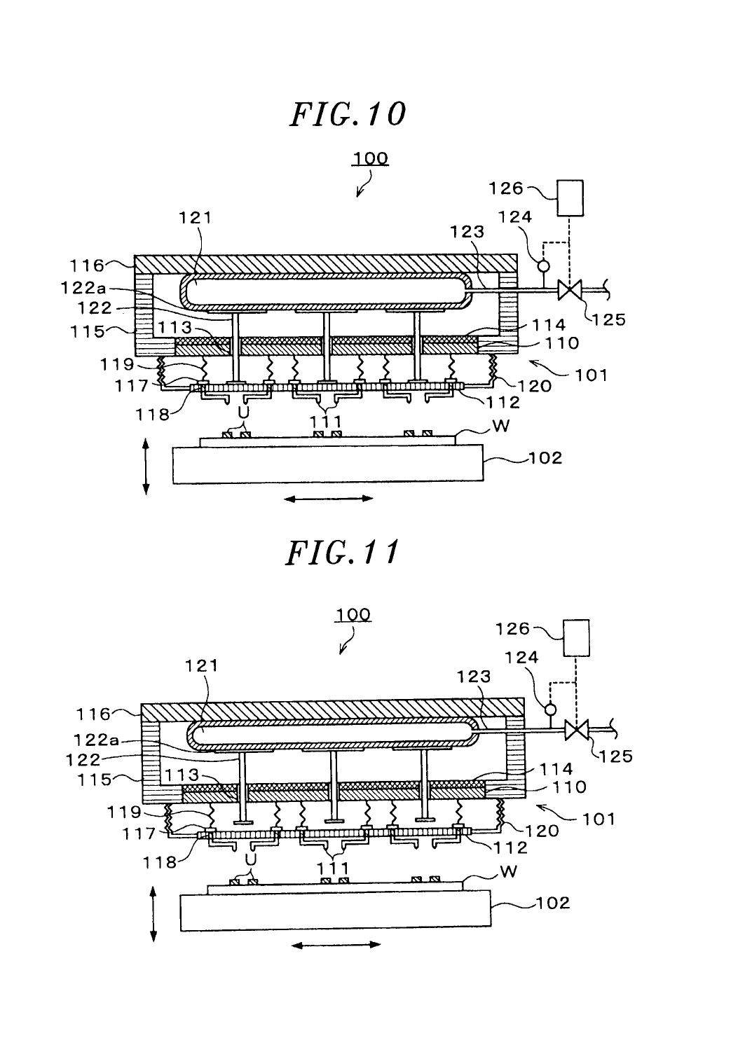

Next, another embodiment will be described. FIG. 10 is a longitudinal cross sectional view schematically showing a probe apparatus 100 having a probe card in accordance with another embodiment of the present invention.

The probe apparatus 100 includes a probe card 101, and a mounting table 102 for mounting the wafer W as in the probe apparatus 1. The probe card 101 is disposed above the mounting table 102.

The probe card 101 is formed, e.g., in a substantially disc shape, similarly to the probe card 2. The probe card 101 includes a circuit board 110 having an electronic circuit for sending an electric test signal the wafer W mounted on the mounting table 102, and a contactor support plate 112 supporting plural contactors 111 on its lower surface, the contactors 111 being in contact with the electrode pads U of the wafer W during testing.

The circuit board 110 is formed, e.g., in a substantially disc shape having plural through-holes 113. The circuit board 110 is electrically connected to a tester (not shown), and the electric test signal is sent and received between the tester and the contactors 111 through the circuit board 110.

A reinforcing member 114 for reinforcing the circuit board 110 is provided on an upper surface of the circuit board 110 in parallel to the circuit board 110. The reinforcing member 114 is formed, e.g., in a substantially disc shape corresponding to the circuit board 110. Further, a frame body 115 is provided as a holding member at an outer periphery of the circuit board 110. The circuit board 110 and the reinforcing member 114 are held by the frame body 115. A support member 116 is provided above the circuit board 110. The circuit board 110 is supported by the support member 116 through the frame body 115.

The contactor support plate 112 is formed of an elastic material such as Alloy 42, and has, e.g., a substantially disc shape. The contactor support plate 112 is arranged below the circuit board 110 to face the mounting table 102. The contactors 111 supported on the lower surface of the contactor support plate 112 are arranged at positions corresponding to the electrode pads U of the wafer W. Plural connecting terminals 117 are arranged on an upper surface of the contactor support plate 112 at positions corresponding to the contactors 111. The connecting terminals 117 are electrically connected to the contactors 111 through connection wirings 118. The connecting terminals 117 are electrically connected to elastic conductors 119 that are wirings provided on a lower surface of the circuit board 110. The elastic conductors 119 are provided to extend downward vertically from positions of the lower surface of the circuit board 110 corresponding to the connecting terminals 117 toward the contactor support plate 112 such that a wiring distance between the circuit board 110 and the contactors 111 is the shortest distance. Further, the elastic conductors 119 are formed in, e.g., a spring shape, and formed of, e.g., conductive metal with elasticity. Further, the contactors 111 are made of a conductive metal material, such as a nickel alloy, with excellent mechanical characteristics. In this case, the contactors 111 preferably have an elastic structure capable of absorbing a difference in height between the electrode pads U if the electrode pads U have different heights in a local region on the wafer W. Although cantilever type contactors are illustrated as the contactors 111 in FIG. 10, without being limited thereto, the contactors applicable to the present invention may be various contactors having elasticity, e.g., MEMS needles or Pogo pins.

A substantially cylindrical elastic member 120 which is extensible and contractible in a vertical direction is connected to an outer peripheral portion of the contactor support plate 112 as shown in FIG. 10. The elastic member 120 is connected to a lower surface of the frame body 115 disposed above the contactor support plate 112, and the contactor support plate 112 is supported by the frame body 115 through the elastic member 120.

A fluid chamber 121 is provided as a pressing portion above the circuit board 110. The fluid chamber 121 is provided to cover the substantially entire surface of the circuit board 110. The fluid chamber 121 is formed of a flexible material such as rubber, or metal such as stainless steel with a bellows structure, and may be filled with a fluid.

Plural rod-shaped members 122 serving as a pressing force transfer member are arranged above the contactor support plate 112 and below the fluid chamber 121, as shown in FIG. 10, to be inserted into and pass through the through-holes 113 of the circuit board 110, and extend above the circuit board 110. Provided at upper ends of the rod-shaped members 122 are, e.g., plate-shaped contact portions 122a. The contact portions 122a are connected to a lower surface of the fluid chamber 121.

The fluid chamber 121 is provided with a supply pipe 123 serving as a fluid inlet for supplying a fluid into the fluid chamber 121. The supply pipe 123 is connected to a compressed air supply source (not shown) for supplying compressed air. Further, the supply pipe 123 is provided with a pressure gauge 124 for measuring the pressure of compressed air in the supply pipe 123. Further, a valve 125 is provided in the supply pipe 124. Opening/closing of the valve 125 is controlled by a control unit 126 on the basis of a pressure detection signal of the pressure gauge 124. Further, if a predetermined amount of compressed air controlled by opening/closing of the valve 125 is introduced into the fluid chamber 121, the fluid chamber 121 may be extended vertically. Accordingly, the rod-shaped members 122 connected to the lower surface of the fluid chamber 121 are pressed downward, and the pressed rod-shaped members 122 are put in pressure contact with the upper surface of the contactor support plate 112 to transfer a pressing force. Thus, the fluid chamber 121 may apply a predetermined contact pressure to the plural contactors 111 during testing. Further, connecting the upper ends of the rod-shaped members 122 to the fluid chamber 121 is to prevent the fluid chamber 121 from moving in a horizontal direction. For example, instead of connection to the fluid chamber 121, lower ends of the rod-shaped members 122 may be connected to the contactor support plate 112. Also, although the rod-shaped members are used as a pressing force transfer member in this embodiment, without being limited thereto, the pressing force transfer member may have any shape if it can press the contactor support plate 112 by being inserted into and passing through the through-holes 113 of the circuit board 110.

The mounting table 102 is configured to be movable, e.g., in horizontal and vertical directions, and can move the mounted wafer W in three dimensions.

The probe apparatus 100 in accordance with another embodiment of the present invention is configured as described above. Next, a method for testing the electrical characteristics of the electronic circuit of the wafer W, which is carried out in the probe apparatus 100 will be described.

At the start of testing, as shown in FIG. 11, compressed air is not supplied into the fluid chamber 121, and the fluid chamber 121 is in a contracted state.

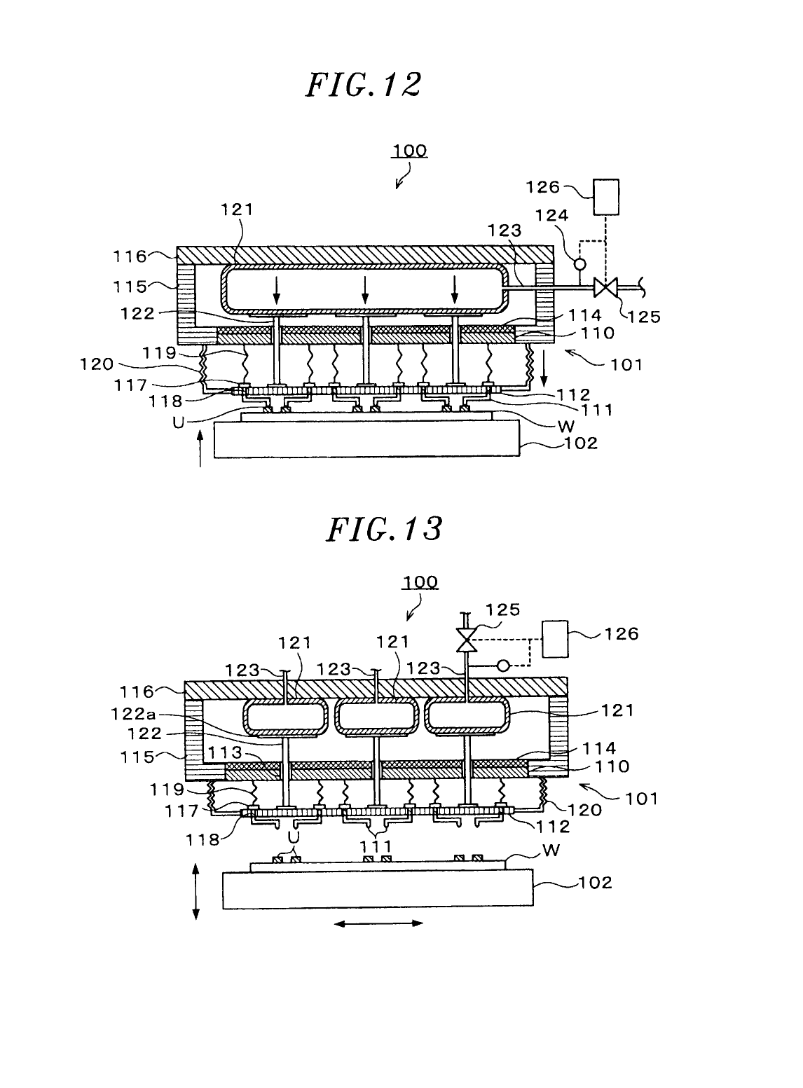

Further, when the wafer W is mounted on the mounting table 102, the mounting table 102 is moved up to a predetermined position as shown in FIG. 12. At the same time or thereafter, the compressed air is supplied into the fluid chamber 121 through the supply pipe 123, and the fluid chamber 121 is filled with a predetermined amount of compressed air. Then, the fluid chamber 121 is extended vertically to press down the contactor support plate 112 through the rod-shaped members 122. Accordingly, the elastic conductors 119 and the elastic member 120 are extended downward, and the contactors 111 are put in contact with the electrode pads U of the wafer W respectively at a predetermined contact pressure.

Then, while the wafer W is pressed to the contactors ill at a predetermined contact pressure, the electric test signals are transmitted from the circuit board 110 to the respective electrode pads U of the wafer W passing through the contactors 111, thereby testing the electrical characteristics of the electronic circuit on the wafer W.

In accordance with the above embodiment, since the contactors 111 have elasticity, it is possible to absorb a difference in height between the electrode pads U if the electrode pads U have different heights in a local region on the wafer W. Meanwhile, if the wafer W or an upper surface of the mounting table 102 has a slope, distortion, positioning error or the like, since the contactor support plate 112 with flexibility is pressed by the fluid chamber 121 provided above the circuit board 110 through the rod-shaped members 122 inserted into and passing through the through-holes 113 of the circuit board 110, stable contact can be achieved at a predetermined contact pressure on the entire probe card 2.

Further, since the fluid chamber 121 is provided above the circuit board 110, when the contactors 111 and the circuit board 110 are electrically connected to each other, the fluid chamber 121 never becomes an obstacle of wiring between the contactors 111 and the circuit board 110. Accordingly, the probe card 101 of this embodiment can respond to even a case where a number of the electrode pads U are formed on the wafer W.

Further, since the fluid chamber 121 never becomes an obstacle of wiring between the contactors 111 and the circuit board 110, it is possible to achieve the same wiring length between the contactors 111 and the circuit board 110. Therefore, the electric signals may be transmitted from the circuit board to the contactors 111 in the same manner, thereby conducting reliable testing.

In this regard, in case of using the probe card 200 disclosed in JP07-94561, wherein the fluid chamber is provided between the circuit board and the contactors, wirings cannot be formed in a lower region A (represented by a dotted line in FIG. 15) of the circuit board 201 located above the support plate 203. Accordingly, when a number of the electrode pads U are formed on the wafer W, the probe card 200 becomes large-sized.

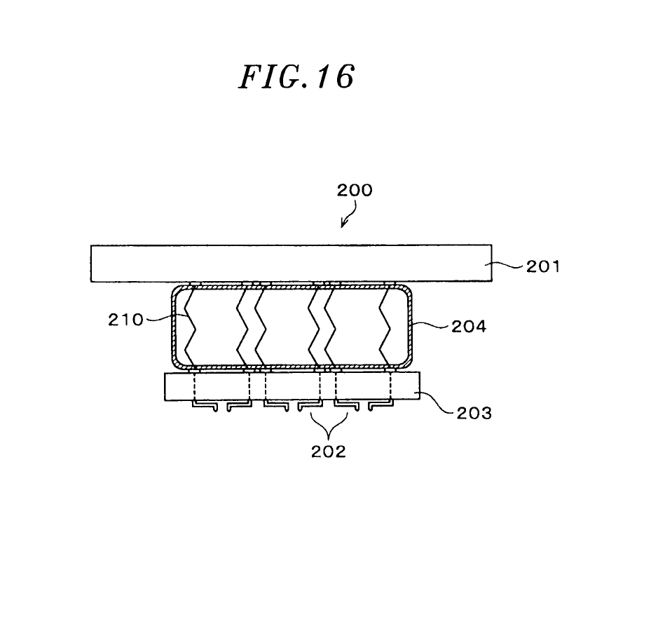

Thus, inventors of the present invention first have tried, for example, as shown in FIG. 16, to solve a problem such as an increase in size of the probe card 200 by arranging wirings 210 in the fluid chamber 204, and effectively using the lower region A in the probe card 200. In this case, since the wirings 210 need to be electrically connected to the circuit board 201 or the contactors 202 during testing, the wirings 210 are arranged to pass through the fluid chamber 204. However, in a case where the wirings 210 are only formed to pass through the fluid chamber 204, a gas or the like leaks from the fluid chamber 204 and it is impossible to ensure airtightness in the fluid chamber 204. Then, it is impossible to make the contactors 202 in stable contact with the electrode pads at a predetermined contact pressure, and it is impossible to appropriately test the electrical characteristics of an object to be tested.

Accordingly, the inventors have conceived the probe card 101 having the above configuration focusing on the point that it is possible to prevent the fluid chamber 121 from being an obstacle of the wirings 210 by providing the fluid chamber 121 above the circuit board 110. Further, according to the probe card 101 of the present invention, since the fluid chamber 121 is provided above the circuit board 110, there is no need to form the wirings to pass through the inside of the fluid chamber 121. Therefore, it is possible to prevent leakage of a gas or the like from the fluid chamber 121, and to make the contactors 111 in stable contact with the electrode pads U at a predetermined contact pressure.

Further, although one fluid chamber 121 is provided in the above embodiment, for example, as shown in FIG. 13, plural fluid chambers 121 may be provided. In this case, it is possible to independently control the contact pressure for each of the fluid chambers 121 by the control unit 126.

Further, although the contact pressure is applied to the contactors 111 by using the fluid chambers 121 and the rod-shaped members 122 in the above embodiment, for example, the fluid chambers 121 may be formed in a shape such that the fluid chambers 121 itself are inserted into and pass through the through-holes 113 of the circuit board 110 to press the contactor support plate 112.

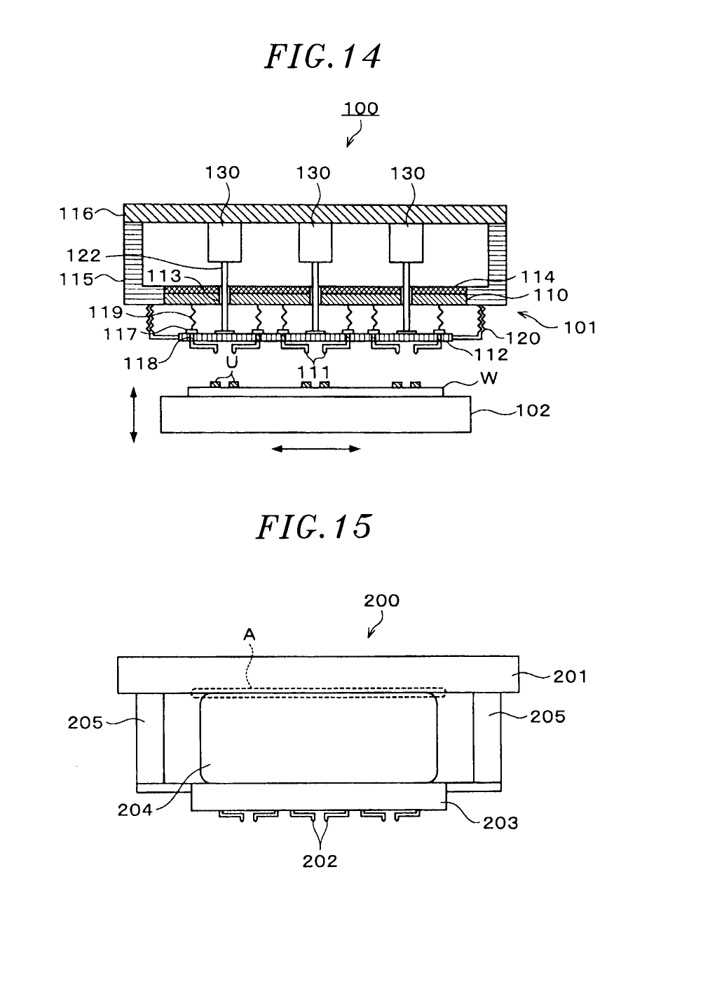

Further, although the fluid chambers 121 are used to apply the contact pressure to the contactors 111 in the above embodiment, for example, as shown in FIG. 14, instead of the fluid chambers 121, plural pressing mechanisms 130 may be used to apply the pressure to the contactors 111. Also in this case, the contact pressure may be independently controlled for each of the pressing mechanisms by the control unit 126. Further, as the pressing mechanisms 130, e.g., a hydraulic cylinder or electric actuator may be used.

As described above, although exemplary embodiments of the present invention have been described with reference to the accompanying drawings, the present invention is not limited thereto. It will be understood by those skilled in the art that various changes and modification may be made without departing from the scope of the invention as defined in the following claims, and they are also included in the technical scope of the present invention. The present invention is not limited to the exemplary embodiments, and may be implemented in various aspects. The present invention may be also applied to cases of using other types of substrates such as a flat panel display (FPD) and a mask reticle for photomask other than the wafer.

The present invention is advantageous when testing the electrical characteristics of an object to be tested such as a semiconductor wafer.

What is claimed is:

1. A probe card for testing electrical characteristics of an object to be tested, comprising:
a plurality of contactors for contacting the object during the testing;
a plurality of tester chips configured to send and receive electric test signals to and from the object to test the electrical characteristics of the object;
a conductive portion electrically connecting the contactors with the corresponding tester chips, the contactors being arranged on a lower surface of the conductive portion; and
a pressing portion configured to press the conductive portion against the object during the testing, so that a pressing force is applied between the contactors and the object.

2. The probe card of claim 1, wherein the contactors are supported by a contactor support plate with elasticity, and the contactor support plate is provided below the conductive portion.

3. The probe card of claim 2, wherein the conductive portion has a flexible insulating layer and a wiring layer formed in the insulating layer.

4. The probe card of claim 3, wherein the pressing portion is configured by bonding the conductive portion, an elastic member hermetically connected to an outer peripheral portion of the conductive portion, and a support member provided above the tester chips,
the pressing portion is configured to be filled with a fluid, and
the tester chips are accommodated in the pressing portion.

5. The probe card of claim 4, further comprising flat plate-shaped mounting substrates on which the tester chips are mounted,
wherein the mounting substrates are arranged in an upright posture above the conductive portion at positions corresponding to the contactors, and
the mounting substrates and the conductive portion are electrically connected to each other.

6. The probe card of claim 5, wherein connecting members to which the mounting substrates are detachably attached are provided on an upper surface of the conductive portion, and
the mounting substrates and the conductive portion are electrically connected to each other via the connecting members.

7. The probe card of claim 4, wherein the pressing portion has a fluid inlet through which a fluid is supplied into the pressing portion, and a fluid outlet through which the fluid is discharged from the pressing portion.

8. The probe card of claim 5, wherein the pressing portion has a fluid inlet through which a fluid is supplied into the pressing portion, and a fluid outlet through which the fluid is discharged from the pressing portion, and
wherein the mounting substrates are arranged substantially in parallel to a flow of the fluid formed in the pressing portion by the fluid inlet and the fluid outlet.

9. The probe card of claim 4, wherein the conductive portion is electrically connected to a control unit configured to supply a power to the tester chips, and send and receive test data and a control signal required for the testing.

10. The probe card of claim 9, wherein the conductive portion has a plurality of contactor wiring portions electrically connecting the contactors with the corresponding tester chips, and an external wiring portion electrically connecting the tester chips with the control unit;
the contactor wiring portions are stacked on an upper surface of the contactor support plate, and disposed below the corresponding tester chips; and
the external wiring portion is provided on upper surfaces of the contactor wiring portions.

11. A probe card for testing electrical characteristics of an object to be tested, comprising:
a circuit board having a through-hole;
a plurality of contactors for contacting the object;
a contactor support plate provided below the circuit board to support the contactors; and
a pressing portion configured to pass through the through-hole of the circuit board from an upper side of the circuit board during the testing to press the contactor support plate against the object, so that a pressing force is applied between the contactors and the object.

12. The probe card of claim 11, wherein a pressing force transfer member is provided between the pressing portion and the contactor support plate to transfer the pressing force of the pressing portion to the contactor support plate, and
the pressing force transfer member passes through the through-hole of the circuit board.

13. The probe card of claim 11, wherein the pressing portion includes a flexible fluid chamber capable of being filled with a fluid.

14. The probe card of claim 11, wherein the contactors and the circuit board are electrically connected to each other by elastic conductors.

15. The probe card of claim 11, wherein the circuit board is supported by a support plate provided on an upper surface of the pressing portion via a holding member holding an outer peripheral portion of the circuit board, and
the contactor support plate is supported by the holding member via an elastic member supported by the holding member.
